(19) United States
(12) Patent Application Publication
(10) Pub. No.: US 2025/0389051 A1
(43) Pub. Date: Dec. 25, 2025

(54) GROUP-III ELEMENT NITRIDE SUBSTRATE AND METHOD OF PRODUCING GROUP-III ELEMENT NITRIDE SUBSTRATE

(71) Applicant: NGK INSULATORS, LTD., Nagoya-shi (JP)

(72) Inventors: Yoshitaka KURAOKA, Okazaki-shi (JP); Kei HIRAIWA, Nagoya-shi (JP); Kentaro NONAKA, Gifu-shi (JP)

(21) Appl. No.: 19/317,370

(22) Filed: Sep. 3, 2025

Related U.S. Application Data
(63) Continuation of application No. PCT/JP2023/008070, filed on Mar. 3, 2023.

(51) Int. Cl. C30B 29/40; C30B 25/18; C30B 35/00

(52) U.S. Cl. CPC C30B 29/406; C30B 25/18; C30B 35/002

(57) ABSTRACT

A Group-III element nitride substrate includes a first main surface and a second main surface facing each other. The Group-III element nitride substrate has a first direction, which extends in a surface direction, and in which a carrier concentration or a defect density is decreased from a first end portion side to a second end portion side, in a substrate surface of the Group-III element nitride substrate.

### CROSS-REFERENCE TO RELATED APPLICATIONS

This application is a continuation application of International Application PCT/JP2023/008070, filed on Mar. 3, 2023, the entire contents of which is incorporated herein by reference.

### BACKGROUND OF THE INVENTION

### 1. Field of the Invention

One or more embodiments of the present invention relate to a Group-III element nitride substrate and a method of producing a Group-III element nitride substrate.

### 2. Description of the Related Art

Group-III element nitride substrates have been used as the substrates of various devices, such as a light-emitting diode, a semiconductor laser, and a power IC.

The Group-III element nitride substrate may be obtained by, for example, as described in JP 2005-136167 A, adopting, as a base substrate, a substrate including a material different in composition such as a sapphire substrate, and epitaxially growing a Group-III element nitride crystal on the base substrate so that the crystal has a larger thickness.

### SUMMARY OF THE INVENTION

However, the Group-III element nitride substrate obtained by the epitaxial growth on the above-mentioned base substrate formed of a different material has a problem in that warping is liable to occur.

In view of the foregoing, a primary object of at the least one embodiment of the present invention is to provide a Group-III element nitride substrate in which the occurrence of warping is suppressed.
1. According to an embodiment of the present invention, there is provided a Group-III element nitride substrate, comprising a first main surface and a second main surface facing each other, wherein the Group-III element nitride substrate has a first direction, which extends in a surface direction, and in which a carrier concentration is decreased from a first end portion side to a second end portion side, in a substrate surface of the Group-III element nitride substrate.
2. In the Group-III element nitride substrate according to the above-mentioned item 1, the carrier concentration may be monotonously decreased from the first end portion side to the second end portion side in the first direction.
3. In the Group-III element nitride substrate according to the above-mentioned item 1 or 2, the carrier concentration on a line along the first direction may have a distribution of 7% or more.
4. In the Group-III element nitride substrate according to the above-mentioned item 3, the Group-III element nitride substrate may have a second direction, which extends in the surface direction, and which is perpendicular to the first direction, in the substrate surface, and the carrier concentration on a line along the second direction may have a distribution of less than 7%.
5. In the Group-III element nitride substrate according to the above-mentioned item 1 or 2, the carrier concentration on a line along the first direction may have a distribution of 10% or more.
6. In the Group-III element nitride substrate according to the above-mentioned item 5, he Group-III element nitride substrate may have a second direction, which extends in the surface direction, and which is perpendicular to the first direction, in the substrate surface, and the carrier concentration on a line along the second direction may have a distribution of less than 10%.
7. According to another embodiment of the present invention, there is provided a Group-III element nitride substrate, comprising a first main surface and a second main surface facing each other, wherein the Group-III element nitride substrate has a first direction, which extends in a surface direction, and in which a defect density is decreased from a first end portion side to a second end portion side, in a substrate surface of the Group-III element nitride substrate.
8. In the Group-III element nitride substrate according to the above-mentioned item 7, the defect density may be monotonously decreased from the first end portion side to the second end portion side in the first direction.
9. In the Group-III element nitride substrate according to the above-mentioned item 7 or 8, the defect density on a line along the first direction may have a distribution of 30% or more.
10. In the Group-III element nitride substrate according to the above-mentioned item 9, the Group-III element nitride substrate may have a second direction, which extends in the surface direction, and which is perpendicular to the first direction, in the substrate surface, and the defect density on a line along the second direction may have a distribution of less than 30%.
11. In the Group-III element nitride substrate according to the above-mentioned item 7 or 8, the defect density on a line along the first direction may have a distribution of 50% or more.
12. In the Group-III element nitride substrate according to the above-mentioned item 11, the Group-III element nitride substrate may have a second direction, which extends in the surface direction, and which is perpendicular to the first direction, in the substrate surface, and the defect density on a line along the second direction may have a distribution of less than 50%.
13. In the Group-III element nitride substrate according to any one of the above-mentioned items 1 to 12, the first direction may substantially correspond to a direction in which a c-axis of a Group-III element nitride crystal is tilted with respect to a normal of the main surface in plan view.
14. In the Group-III element nitride substrate according to the above-mentioned item 13, an angle of the tilt may be more than 0° and less than 1°.
15. In the Group-III element nitride substrate according to any one of the above-mentioned items 1 to 14, the Group-III element nitride substrate may be a freestanding substrate of a Group-III element nitride crystal.
16. According to an embodiment of the present invention, there is provided a method of producing the Group-III element nitride substrate of any one of the above-mentioned items 1 to 15, the method comprising: preparing a seed crystal substrate including: a base substrate including an upper surface and a lower surface facing each other; and a seed crystal film to be formed on the upper surface of the base substrate; growing a Group-III element nitride crystal on the seed crystal film of the seed crystal substrate by a flux method; and removing the base substrate from the Group-III element nitride crystal, wherein the growing the Group-III element nitride crystal by the flux method is performed by arranging the seed crystal substrate on a mounting table that is rotated about a vertical axis, wherein a center of the seed crystal substrate is spaced apart from a rotation axis of the mounting table, and wherein the seed crystal substrate is arranged so that an angle formed by an off-angle direction of the seed crystal film of the seed crystal substrate and a normal of the rotation axis of the mounting table that passes through the center of the seed crystal substrate is substantially 0° in plan view.
17. In the production method according to the above-mentioned item 16, the base substrate may contain a material different in composition from the Group-III element nitride crystal.

### BRIEF DESCRIPTION OF THE DRAWINGS

FIG. 1 is a schematic sectional view for illustrating the schematic configuration of a Group-III element nitride substrate according to at least one embodiment of the present invention.

FIG. 2 is a plan view of the Group-III element nitride substrate illustrated in FIG. 1.

FIG. 3A is a view for illustrating a production process for a Group-III element nitride substrate according to at least one embodiment of the present invention.

FIG. 3B is a view subsequent to FIG. 3A.

FIG. 3C is a view subsequent to FIG. 3B.

FIG. 4A is a perspective view for illustrating an example of the state in which crucibles are mounted on a mounting table in a pressure space of a growth apparatus.

FIG. 4B is a view of the positional relationship between the mounting table and the crucibles illustrated in FIG. 4A when viewed from above.

FIG. 4C is a view for illustrating an example of the state of a liquid surface in the crucible at the time of rotation.

FIG. 5A is a sectional view for illustrating an example of warping that may occur in a laminated substrate.

FIG. 5B is a sectional view for illustrating an example of warping that may occur in a freestanding substrate.

FIG. 6 is a schematic sectional view for illustrating the schematic configuration of a device substrate according to one embodiment of the present invention.

FIG. 7 is an explanatory view for illustrating measurement sites.

### DESCRIPTION OF THE EMBODIMENTS

Embodiments of the present invention are described below with reference to the drawings. The present invention is not limited to those embodiments. For clearer illustration, some widths, thicknesses, shapes, and the like of respective portions may be schematically illustrated in the drawings in comparison to the embodiments. However, the widths, the thicknesses, the shapes, and the like are each merely an example, and do not limit the understanding of the present invention.

In addition, in the drawings, the same or similar elements are denoted by the same reference symbols, and repetitive description thereof may be omitted.

### A. Group-III Element Nitride Substrate

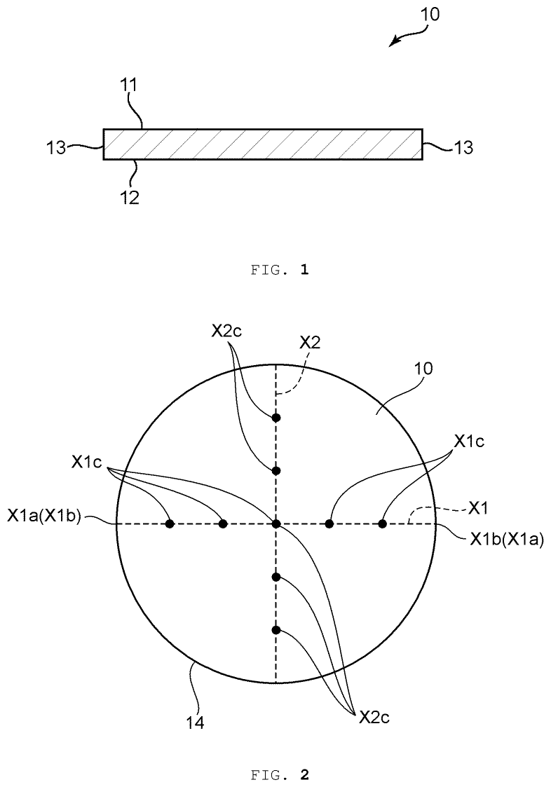

FIG. 1 is a schematic sectional view for illustrating the schematic configuration of a Group-III element nitride substrate according to at least one embodiment of the present invention. FIG. 2 is a plan view of the Group-III element nitride substrate illustrated in FIG. 1. A Group-III element nitride substrate 10 has a plate shape and includes a first main surface 11 and a second main surface 12 facing each other. The main surfaces are linked to each other via a side surface 13. As illustrated in FIG. 2, the Group-III element nitride substrate 10 includes an outer peripheral edge 14. In the illustrated example, the outer peripheral edge 14 has a circular shape, but for example, an orientation flat or a notch may be formed in a part of the outer peripheral edge 14 in order to show a crystal orientation (e.g., a crystal orientation of a wafer).

In the illustrated examples, the Group-III element nitride substrate has a disc shape (wafer), but the shape is not limited thereto and any appropriate shape may be adopted. The size of the Group-III element nitride substrate be appropriately set in accordance with purposes. The diameter of the Group-III element nitride substrate having a disc shape is, for example, 50 mm or more and 200 mm or less, and may be 75 mm or more, or 100 mm or more. According to the Group-III element nitride substrate having a large size (e.g., having a diameter of 75 mm or more), for example, the productivity of a device having a large size can be improved.

The thickness of the Group-III element nitride substrate is, for example, 250 μm or more and 800 μm or less, preferably 300 μm or more and 750 μm or less, more preferably 350 μm or more and 725 μm or less.

The Group-III element nitride substrate includes a Group-III element nitride crystal. For example, aluminum (Al), gallium (Ga), or indium (In) is used as a Group-III element for forming a Group-III element nitride. Those elements may be used alone or in combination thereof. Specific examples of the Group-III element nitride include aluminum nitride (AlₓN), gallium nitride (Ga_{y}N), indium nitride (In_{z}N), aluminum gallium nitride (AlₓGa_{y}N), gallium indium nitride (Ga_{y}In_{z}N), aluminum indium nitride (AlₓIn_{z}N), and aluminum gallium indium nitride (AlₓGa_{y}In_{z}N). In each of the chemical formulae in parentheses, typically, x+y+z=1 is satisfied.

The Group-III element nitride may contain a dopant. Examples of the dopant include: p-type dopants, such as beryllium (Be), magnesium (Mg), strontium (Sr), cadmium (Cd), iron (Fe), manganese (Mn), and zinc (Zn); and n-type dopants, such as silicon (Si), germanium (Ge), tin (Sn), and oxygen (O). Those dopants may be used alone or in combination thereof.

In the Group-III element nitride crystal, typically, the <0001> direction is the c-axis direction, the <1-100> direction is the m-axis direction, and the <11-20> direction is the a-axis direction. In addition, the crystal plane perpendicular to the c-axis is the c-plane, the crystal plane perpendicular to the m-axis is the m-plane, and the crystal plane perpendicular to the a-axis is the a-plane.

In one embodiment, the thickness direction of the Group-III element nitride substrate 10 is substantially the c-axis direction. Specifically, the thickness direction of the Group-III element nitride substrate 10 is parallel or approximately parallel to the c-axis. In addition, substantially, the first main surface 11 is Group-III element polar surface on (0001) plane side, and the second main surface 12 is nitrogen polar surface on (000-1) plane side. Specifically, the first main surface 11 may be parallel to (0001) plane, or may be tilted with respect to the (0001) plane. The angle of the tilt of the first main surface 11 with respect to the (0001) plane is, for example, 10° or less, and may be 5° or less, 2° or less, or 1° or less. The second main surface 12 may be parallel to (000-1) plane, or may be tilted with respect to the (000-1) plane. The angle of the tilt of the second main surface 12 with respect to the (000-1) plane is, for example, 10° or less, and may be 5° or less, 2° or less, or 1° or less. Here, the term “thickness direction” refers to a direction perpendicular to the main surface, that is, the normal direction of the main surface. The angle (off-angle) formed by the normal of the main surface of the Group-III element nitride substrate 10 and the c-axis is preferably more than 0° and less than 1°, and may be from 0.3° to 0.5°.

The carrier concentration of the Group-III element nitride substrate 10 is preferably 1×10¹⁸ cm⁻³ or more, more preferably 2×10¹⁸ cm⁻³ or more, still more preferably 3×10¹⁸ cm⁻³ or more. Meanwhile, the carrier concentration of the Group-III element nitride substrate 10 is, for example, 1×10²⁰ cm⁻³ or less, may be 5×10¹⁹ cm⁻³ or less, or may be 2×10¹⁹ cm⁻³ or less. The carrier concentration of the Group-III element nitride substrate 10 may be determined by, for example, Hall effect measurement using the van der Pauw method.

The defect density of the Group-III element nitride substrate 10 evaluated by a cathode luminescence method is preferably 5×10⁶ cm⁻² or less, more preferably 1×10⁶ cm⁻² or less. Meanwhile, the defect density of the Group-III element nitride substrate 10 evaluated by the cathode luminescence method may be, for example, 1×10⁴ cm⁻² or more.

The Group-III element nitride substrate 10 has a first direction X1 extending in a surface direction in a substrate surface. In the first direction X1, the carrier concentration may be decreased from a first end portion X1a side to a second end portion X1b side. For example, as illustrated in FIG. 2, the carrier concentrations at a plurality of points X1c located on a line along the first direction X1 may be decreased from the first end portion X1a side to the second end portion X1b side. The carrier concentration may be monotonously decreased from the first end portion X1a side to the second end portion X1b side on the line along the first direction X1. When the Group-III element nitride substrate 10 has the first direction X1 in which the carrier concentration is s changed as described above, the occurrence of warping can be suppressed.

Typically, the first direction X1 may substantially correspond to a direction in which the above-mentioned c-axis is tilted with respect to the normal of the main surface of the Group-III element nitride substrate 10 (off-angle direction) in plan view. For example, the first direction X1 is the m-axis direction or the a-axis direction. In the first main surface (e.g., the Group-III element polar surface) 11, the direction from the first end portion X1a to the second end portion X1b preferably corresponds to a direction in which the above-mentioned c-axis is tilted with respect to the normal of the main surface of the Group-III element nitride substrate 10 (off-angle direction) in plan view.

When the first direction X1 is the a-axis direction, the distribution of the carrier concentration on the line along the first direction X1 of the Group-III element nitride substrate 10 is preferably 7% or more, more preferably 10% or more. Meanwhile, the distribution of the carrier concentration on the line along the first direction X1 of the Group-III element nitride substrate 10 is preferably less than 15%. The distribution of the carrier concentration on the line along the first direction X1 may be calculated from measurement values obtained by measurement at the plurality of points Xlc. The Group-III element nitride substrate 10 has a second direction X2, which extends in the surface direction, and which is perpendicular to the first direction X1, in the substrate surface. The distribution of the carrier concentration on a line along the second direction X2 of the Group-III element nitride substrate 10 is preferably less than 7%, more preferably 5% or less. The difference between the distribution of the carrier concentration on the line along the first direction X1 and the distribution of the carrier concentration on the line along the second direction X2 is preferably 8% or more. The distribution of the carrier concentration on the line along the second direction X2 may be calculated from measurement values obtained by measurement at a plurality of points X2c located on the line along the second direction X2.

When the first direction X1 is the m-axis direction, the distribution of the carrier concentration on the line along the first direction X1 of the Group-III element nitride substrate 10 is preferably 10% or more, more preferably 15% or more. Meanwhile, the distribution of the carrier concentration on the line along the first direction X1 of the Group-III element nitride substrate 10 is preferably less than 20%. The distribution of the carrier concentration on the line along the second direction X2 of the Group-III element nitride substrate 10 is preferably less than 10%, more preferably 5% or less. The difference between the distribution of the carrier concentration on the line along the first direction X1 and the distribution of the carrier concentration on the line along the second direction X2 is preferably 12% or more.

In the first direction X1, the defect density may be decreased from the first end portion X1a side to the second end portion X1b side. For example, as illustrated in FIG. 2, the defect densities at the plurality of points X1c located on the line along the first direction X1 may be decreased from the first end portion X1a side to the second end portion X1b side. The defect density may be monotonously decreased from the first end portion X1a side to the second end portion X1b side on the line along the first direction X1. When the Group-III element nitride substrate 10 has the first direction X1 in which the defect density is changed as described above, the occurrence of warping can be suppressed.

When the first direction X1 is the a-axis direction, the distribution of the defect density on the line along the first direction X1 of the Group-III element nitride substrate 10 is preferably 30% or more, more preferably 40% or more. Meanwhile, the distribution of the defect density on the line along the first direction X1 of the Group-III element nitride substrate 10 is preferably less than 70%. The distribution of the defect density on the line along the first direction X1 may be calculated from measurement values obtained by measurement at the plurality of points X1c. The distribution of the defect density on the line along the second direction X2 of the Group-III element nitride substrate 10 is preferably less than 30%, more preferably 20% or less. The difference between the distribution of the defect density on the line along the first direction X1 and the distribution of the defect density on the line along the second direction X2 is preferably 30% or more. The distribution of the defect density on the line along the second direction X2 may be calculated from measurement values obtained by measurement at the plurality of points X2c located on the line along the second direction X2.

When the first direction X1 is the m-axis direction, the distribution of the defect density on the line along the first direction X1 of the Group-III element nitride substrate 10 is preferably 50% or more, more preferably 70% or more. Meanwhile, the distribution of the defect density on the line along the first direction X1 of the Group-III element nitride substrate 10 is preferably less than 100%. The distribution of the defect density on the line along the second direction X2 of the Group-III element nitride substrate 10 is preferably less than 50%, more preferably 30% or less, still more preferably 20% or less. The difference between the distribution of the defect density on the line along the first direction X1 and the distribution of the defect density on the line along the second direction X2 is preferably 65% or more.

In the Group-III element nitride substrate according to the embodiment of the present invention, the occurrence of warping can be satisfactorily suppressed. Specifically, when the above-mentioned relationship of the carrier concentration and/or the defect density is satisfied in the first direction present in the substrate surface of the Group-III element nitride substrate, the occurrence of warping can be satisfactorily suppressed. As a result of repeated trial and error in addressing the problem of warping, it has been found that warping can be improved by controlling the above-mentioned distribution of the carrier concentration and/or the defect density in the first direction present in the substrate surface. When the size (e.g., the diameter) of the Group-III element nitride substrate is increased, warping is more liable to occur, and the degree of warping is liable to be increased. However, according to the embodiment of the present invention, even when the size of the Group-III element nitride substrate is large, the occurrence of warping can be satisfactorily suppressed.

The above-mentioned degree of warp may be evaluated by, for example, interference method, and may also be evaluated by height difference measurement using a non-contact displacement meter that uses a laser or the like. The evaluation method may be appropriately selected depending on the state of a surface to be measured. It is preferred that the warp be suppressed to, for example, less than 30 μm.

### B. Production Method

A method of producing a Group-III element nitride substrate according to one embodiment of the present invention includes: preparing a seed crystal substrate including a base substrate and a seed crystal film; growing a Group-III element nitride crystal on the seed crystal film of the seed crystal substrate; and removing the base substrate from the Group-III element nitride crystal.

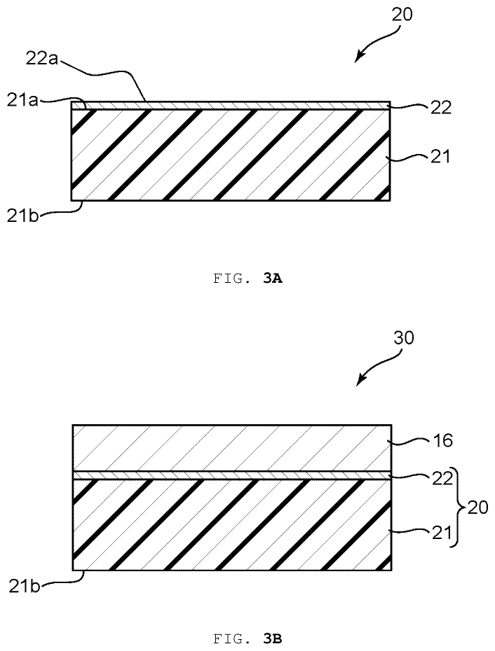

FIG. 3A to FIG. 3C are each a view for illustrating a production process for a Group-III element nitride substrate according to at least one embodiment of the present invention. In FIG. 3A, there is illustrated a state in which a seed crystal film 22 has been formed on an upper surface 21a of a base substrate 21 including the upper surface 21a and a lower surface 21b facing each other to complete a seed crystal substrate 20.

For example, a substrate having such a shape and size that a Group-III element nitride substrate having a desired shape and size can be produced is used as the base substrate. Typically, the base substrate has a disc shape having a diameter of from 50 mm to 200 mm. The thickness of the base substrate is, for example, from 300 μm to 2000 μm.

Any appropriate substrate may be used as the base substrate. The base substrate typically includes a monocrystalline body. Examples of a material for forming the base substrate include sapphire, crystal-oriented alumina, silicon, gallium oxide, aluminum gallium nitride, gallium arsenide, and silicon carbide (SiC). Of those, sapphire is preferably used.

In one embodiment, the base substrate has a main surface, and an angle (off-angle) formed by the normal of the main surface and a c-axis of a crystal forming the base substrate is preferably more than 0° and less than 1°, and may be from 0.3° to 0.5°.

The thickness of the above-mentioned seed crystal film is, for example, from 0.2 μm to 5 μm, preferably from 1 μm to 4 μm. Any appropriate material may be adopted as a material for forming the seed crystal film. A Group-III element nitride is typically used as the material for forming the seed crystal film. In one embodiment, gallium nitride is used.

The seed crystal film may be formed by any appropriate method. A vapor phase epitaxy method is typically used as a method of forming the seed crystal film. Specific examples of the vapor phase epitaxy method include a metal-organic chemical vapor deposition (MOCVD) method, a hydride vapor phase epitaxy (HVPE) method, a pulsed excitation deposition (PXD) method, a molecular-beam epitaxy (MBE) method, and a sublimation method. Of those, an MOCVD method is preferably used.

The formation of the seed crystal film by the MOCVD method includes, for example, a first formation step and a second formation step in the stated order. Specifically, the first formation step includes forming a first layer (low-temperature grown buffer layer) (not shown) on the base substrate at a temperature T1 (e.g., from 450° C. to 550° C.), and the second formation step includes forming a second layer (not shown) at a temperature T2 (e.g., from 1,000° C. to 1, 200° C.) higher than the temperature T1. The thickness of the first layer is, for example, from 20 nm to 50 nm. The thickness of the second layer is, for example, from 1 μm to 4 μm.

The direction in which a c-axis of a crystal forming the seed crystal film 22 is tilted with respect to the normal of a surface 22a of the seed crystal film 22 that is a main surface of the seed crystal substrate 20 (off-angle direction of the seed crystal film 22) may be typically the same as the off-angle direction of the base substrate 21.

Next, a Group-III element nitride crystal is grown on the seed crystal film 22 of the seed crystal substrate 20 to form a Group-III element nitride crystal layer 16. Thus, a laminated substrate 30 is obtained as illustrated in FIG. 3B. The degree of growth of the Group-III element nitride crystal (thickness of the Group-III element nitride crystal layer 16) may be adjusted in accordance with a desired thickness of the Group-III element nitride substrate. Any appropriate direction may be selected as the growth direction of the Group-III element nitride crystal in accordance with, for example, usages or purposes. Specific examples thereof include: the normal direction of each of the above-mentioned c-plane, a-plane, and m-plane; and the normal direction of a plane tilted with respect to each of the above-mentioned c-plane, a-plane, and m-plane.

The Group-III element nitride crystal may be grown by any appropriate method. The method of growing the Group-III element nitride crystal is not particularly limited as long as a crystal direction substantially following the crystal direction of the above-mentioned seed crystal film can be achieved by the method. Specific examples of the method of growing the Group-III element nitride crystal include: vapor growth methods, such as a metal-organic chemical vapor deposition (MOCVD) method, a hydride vapor phase epitaxy (HVPE) method, a pulsed excitation deposition (PXD) method, a molecular-beam epitaxy (MBE) method, and a sublimation method; liquid phase growth methods, such as a flux method, an ammonothermal method, a hydrothermal method, and a sol-gel method; and a solid phase growth method utilizing grain growth of powder. Those methods may be used alone or in combination thereof.

The flux method (e.g., Na flux method) is preferably adopted as the method of growing the Group-III element nitride crystal. The growth of the Group-III element nitride crystal by the flux method is typically performed through use of a crucible as a growth vessel. Specifically, the above-mentioned seed crystal substrate is placed in the crucible, and further, flux and raw materials are filled into the crucible. The crucible having the seed crystal substrate placed therein is typically placed at any appropriate pressure and temperature an under atmosphere containing nitrogen under a state of being covered with a lid, and is subjected to growth treatment.

The growth by the flux method may be performed with, for example, an apparatus as described in Japanese Patent No. 5244628. Specifically, the growth by the flux method may be performed with a growth apparatus including: a pressure-resistant vessel to which a pressurized nitrogen gas can be supplied; a rotary table rotatable in the pressure-resistant vessel; and an outer vessel which is mounted on the rotary table and accommodates the crucible. In addition, for example, the growth by the flux method may be performed with an apparatus as described in Japanese U.S. Pat. No. 5,182,944. Specifically, the growth by the flux method may be performed with a growth apparatus including a pressure vessel which accommodates a crucible and into which a nitrogen gas is to be filled and a heating unit that heats the crucible.

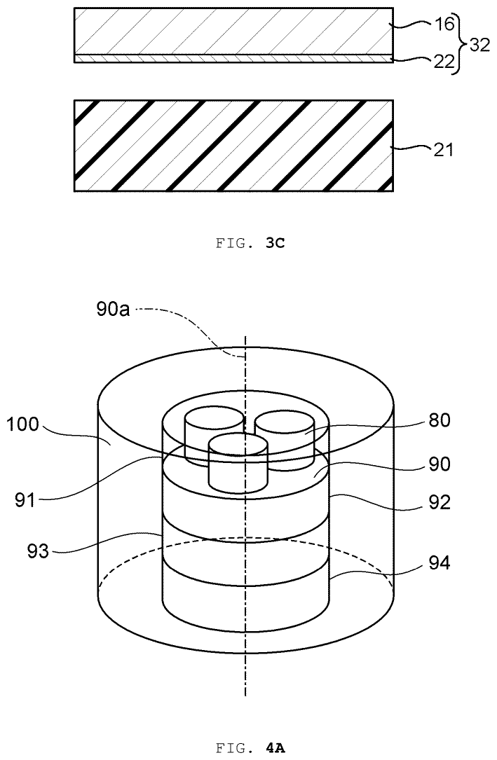

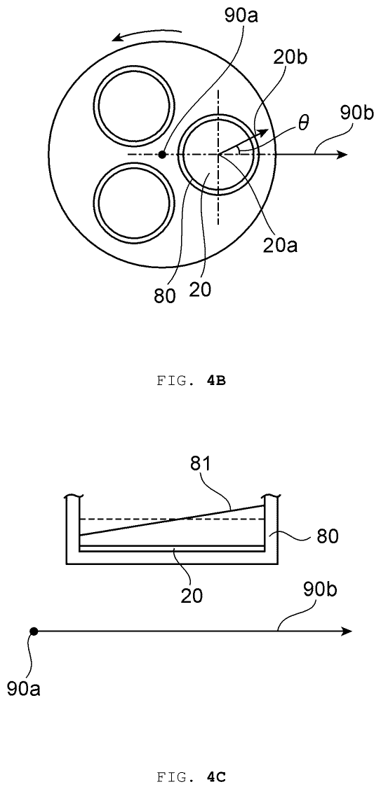

In one embodiment, the growth of the Group-III element nitride crystal is performed under a state in which a crucible having a seed crystal substrate placed therein is mounted on a mounting table and the mounting table is being rotated (e.g., spinning on its own axis). FIG. 4A is a perspective view for illustrating an example of the state in which crucibles are mounted on a mounting table in a pressure space of a growth apparatus, and FIG. 4B is a view of the positional relationship between the mounting table and the crucibles illustrated in FIG. 4A when viewed from above.

In the example illustrated in FIG. 4A, from the viewpoints of production efficiency and the like, a plurality of growth zones 91 to 94 are arranged in a pressure vessel 100 that is a growth furnace. In each of the growth zones, a plurality of (three in the illustrated example) crucibles 80 may be mounted on a horizontal mounting table 90. A growth apparatus includes a rotation unit (not shown) that rotates the mounting table 90 about its vertical axis. A rotation axis 90a of the mounting table 90 typically passes through the center of the mounting table 90. The crucible 80 is arranged so that a center 20a of the seed crystal substrate 20 to be placed therein is spaced apart from the rotation axis 90a. In FIG. 4A, the growth zones 91 to 94 cannot be visually recognized from the outside, but are indicated by solid lines for convenience.

As illustrated in FIG. 4B, the crucible 80 may be mounted so that an off-angle direction 20b of the seed crystal film 22 of the seed crystal substrate 20 placed in the crucible 80 forms an angle θ with respect to a normal 90b of the rotation axis 90a of the mounting table 90 that passes through the center 20a of the seed crystal substrate 20. Here, the angle θ may be measured so that a counterclockwise direction is positive (+) with respect to the normal 90b of the rotation axis 90a of the mounting table 90 as illustrated in FIG. 4B.

The crucible 80 is preferably mounted so that the angle θ is substantially 0°. Specifically, the crucible 80 is arranged so that the off-angle direction 20b of the seed crystal film 22 of the seed crystal substrate 20 placed in the crucible 80 is aligned with the normal 90b of the rotation axis 90a of the mounting table 90. Here, the term “substantially 0°” may include not only 0° but also ±5° from 0°. According to such arrangement, the above-mentioned relationship of the carrier concentration and/or the defect density can be satisfactorily satisfied in a first direction present in a substrate surface of a Group-III element nitride substrate to be obtained. Specifically, the height of a liquid in the crucible may become non-uniform due to the centrifugal force caused by rotation, resulting in non-uniformity in the state of the supply of raw materials to the seed crystal substrate. For example, as illustrated in FIG. 4C, the height of a liquid surface 81 in the crucible 80 at the time of rotation may become higher with distance from the rotation axis. In the flux method, a nitrogen gas is dissolved into a melt from the outside, and hence the crystal growth speed may be accelerated in a site in which the distance between the liquid surface 81 and the seed crystal substrate 20 is small. As a result, it is conceived that a difference is caused in the crystal growth speed in the substrate surface, and for example, a difference may be caused also in an intake speed of an element that serves as a carrier. In addition, for example, it is conceived that a difference may be caused also in defect coalescence and annihilation. When the tilt direction in which the height of the liquid surface 81 is increased is aligned with the off-angle direction 20b of the seed crystal film 22, the above-mentioned relationship of the carrier concentration and/or the defect density can be satisfactorily satisfied in the first direction present in the substrate surface of the Group-III element nitride substrate to be obtained. In FIG. 4C, the broken line indicates the liquid surface when the mounting table is not rotated.

After the growth of the Group-III element nitride crystal, a freestanding substrate 32 is obtained by removing the base substrate 21 from the Group-III element nitride crystal (Group-III element nitride crystal layer 16) as illustrated in FIG. 3C. Typically, as illustrated in FIG. 3C, the freestanding substrate 32 may include the Group-III element nitride crystal layer 16 and the seed crystal film 22. For example, the freestanding substrate 32 is obtained by separating the Group-III element nitride crystal layer 16 from the base substrate 21. The Group-III element nitride crystal may be separated from the base substrate by any appropriate method. As a method of separating the Group-III element nitride crystal, there are given, for example, a method of causing spontaneous separation from the base substrate by utilizing a thermal shrinkage difference between the Group-III element nitride crystal and the base substrate in a temperature decrease step after the growth of the Group-III element nitride crystal, a separation method including chemical etching, and a laser liftoff method including laser light irradiation. Alternatively, a method including grinding and removing the base substrate, a method including using a cutting machine such as a wire saw, and the like are used.

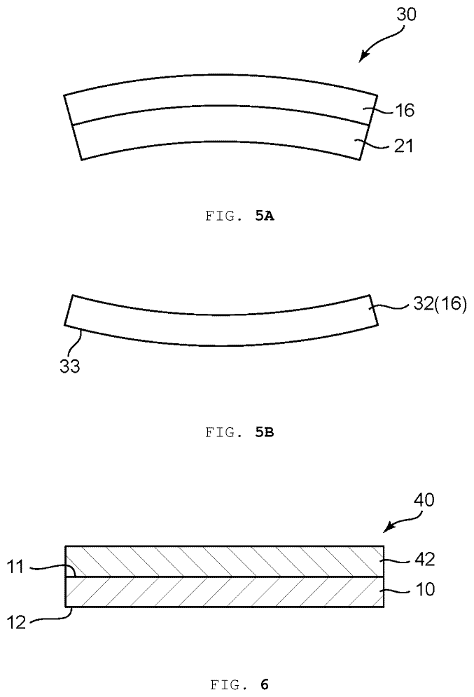

FIG. 5A is a sectional view for illustrating an example of warping that may occur in a laminated substrate. FIG. 5B is a sectional view for illustrating an example of warping that may occur in a freestanding substrate. In FIG. 5A and FIG. 5B, hatching is omitted in a cross-section of each of the laminated substrate and the freestanding substrate for ease of viewing of the drawing. In addition, the illustration of the seed crystal film is omitted for convenience.

In the example illustrated in FIG. 5A, convex warping occurs on the Group-III element nitride crystal layer 16 side in the laminated substrate 30. The base substrate 21 may include a material different in composition (chemical composition) from the Group-III element nitride crystal layer 16. When a Group-III element nitride crystal is heteroepitaxially grown on the base substrate 21, stress may occur owing to a mismatch in a lattice constant or a difference in coefficient of thermal expansion between the base substrate 21 and the Group-III element nitride crystal to be grown, with the result that, for example, strain may be incorporated to cause warping in a laminated substrate 30 to be obtained. The warping may occur, for example, when the temperature of the laminated substrate 30 is decreased after the Group-III element nitride crystal 16 is grown at a high temperature (e.g., from 800° C. to 1, 100° C.). When the coefficient of thermal expansion of the base substrate 21 is larger than the coefficient of thermal expansion of the Group-III element nitride crystal to be grown (e.g., when a sapphire substrate is used as the base substrate), as illustrated in FIG. 5A, convex warping may occur on the Group-III element nitride crystal layer 16 side. Meanwhile, when the coefficient of thermal expansion of the base substrate 21 is smaller than the coefficient of thermal expansion of the Group-III element nitride crystal to be grown (e.g., when a silicon substrate or a SiC substrate is used as the base substrate), convex warping may occur on the base substrate 21 side in contrast to the illustrated example.

It is conceived that, in a growth step of the Group-III element nitride crystal, for example, the growth conditions such as temperature and pressure of a growth atmosphere are changed in order to suppress warping. Depending on an apparatus to be used for performing growth, it may be difficult to change the growth conditions in the growth step, but warping can be satisfactorily suppressed according to the embodiment of the present invention even in such case.

The above-mentioned warping of the laminated substrate may cause warping of the freestanding substrate 32 to be obtained (Group-III element nitride substrate). In the freestanding substrate 32 obtained by removing the base substrate 21 from the laminated substrate 30 illustrated in FIG. 5A, for example, as illustrated in FIG. 5B, the direction of the warping is reversed, and convex warping may occur on a lower surface 33 side on which the base substrate 21 has been arranged.

As described above, in each of the laminated substrate and the freestanding substrate according to the embodiment of the present invention, the carrier concentration and/or the defect density may become non-uniform in the substrate surface in the growth thereof, and the occurrence of warping (e.g., crystal strain or warping in the entire substrate) as described above can be satisfactorily suppressed.

The freestanding substrate 32 may be used as it is for the above-mentioned Group-III element nitride substrate, or the freestanding substrate 32 may be subjected to any appropriate processing to provide the above-mentioned Group-III element nitride substrate.

An example of the processing to which the above-mentioned freestanding substrate is subjected is processing, such as grinding or polishing (e.g., lap polishing or chemical-mechanical polishing (CMP)), of its main surface (upper surface or lower surface). Typically, the freestanding substrate is thinned and flattened by the grinding and the polishing so as to have a desired thickness. In one embodiment, the freestanding substrate may be brought into a state of the Group-III element nitride crystal layer 16 alone (a single crystal growth layer alone) by removing the seed crystal film 22 through the processing of the main surface.

In addition, examples of the processing to which the above-mentioned freestanding substrate is subjected include chamfering of its outer peripheral edge, removal of an affected layer, and removal of a residual stress that may result from the affected layer.

### C. Application

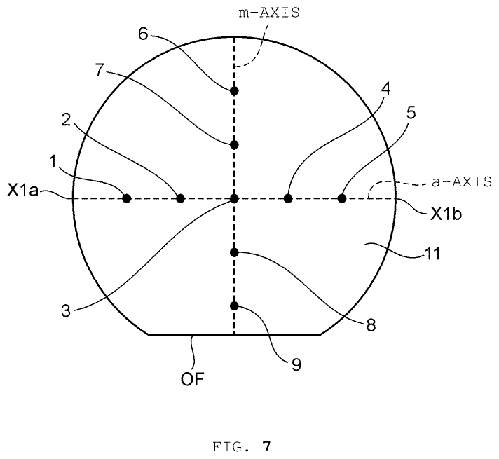

A functional layer may be formed on the above-mentioned Group-III element nitride substrate. FIG. 6 is a schematic sectional view for illustrating the schematic configuration of a device substrate according to one embodiment of the present invention. A device substrate 40 includes the Group-III element nitride substrate 10 and a functional layer 42 formed on the first main surface (e.g., Group-III element polar surface) 11 of the Group-III element nitride substrate 10. The functional layer 42 is typically formed by epitaxially growing a crystal. As described above, the occurrence of warping can be satisfactorily suppressed in the Group-III element nitride substrate 10, and hence the functional layer 42 can be extremely satisfactorily formed. Specifically, in the formation of the functional layer 42, for example, heating unevenness in the surface at the time of heating the Group-III element nitride substrate 10 is prevented, and the functional layer 42 to be obtained has satisfactory uniformity of thickness and composition in the surface, resulting in excellent uniformity of electrical characteristics. In addition, when the Group-III element nitride substrate 10 in which warping is suppressed is used, a device can be satisfactorily produced. For example, a device can be satisfactorily produced by photolithography. Specifically, thickness unevenness of a resist in a resist application step, which may be caused by warping of the substrate, and a decrease in pattern dimensional accuracy and pattern positioning accuracy in separation of an electrode, an insulating layer, and a functional layer in an exposing step can be suppressed, and a device can be produced to a designed size.

The above-mentioned functional layer may function as, for example, a light-emitting layer, a rectifying device layer, a switching device layer, and a power semiconductor layer. In one embodiment, the Group-III element nitride crystal is adopted as a material for forming the above-mentioned functional layer. For example, gallium (Ga), aluminum (Al), or indium (In) is used as a Group-III element for forming a Group-III element nitride. Those elements may be used alone or in combination thereof.

The second main surface (e.g., nitrogen polar surface) 12 of the Group-III element nitride substrate 10 may be subjected to processing, such as grinding or polishing, under a state in which the functional layer 42 has been formed on the Group-III element nitride substrate 10 (under a state in which the device substrate 40 has been formed).

### EXAMPLES

The present invention is specifically described below by way of Experimental Examples, but the present invention is not limited to these Experimental Examples.

### Experimental Example 1-1

### (Production of Seed Crystal Substrate)

A gallium nitride film having a thickness of 3 μm was formed on a sapphire substrate having an off-angle in an m-axis direction, an orientation flat on an a-plane, and a diameter of 100 mm by an MOCVD method, to produce a seed crystal substrate.

### (Growth of Gallium Nitride Crystal)

The growth of a gallium nitride crystal was performed with a growth apparatus including: a pressure vessel which accommodates a crucible and into which a nitrogen gas is filled; a heating unit that heats the crucible; and a rotation unit that rotates the pressure vessel.

The resultant seed crystal substrate was placed in an alumina crucible having a diameter of 200 mm in a glove box under a nitrogen atmosphere. Next, metal gallium and metal sodium were filled into the crucible so that the molar ratio Ga/(Ga+Na) was 15 mol %, and the crucible was covered with an alumina plate. Under this state, the crucible was mounted on a mounting table to be placed in the pressure vessel, and the pressure vessel was sealed. At this time, as illustrated in FIG. 4A and FIG. 4B, the crucible 80 was mounted on the mounting table so that the angle θ formed by the off-angle direction of the seed crystal film (gallium nitride film) of the seed crystal substrate and the normal of the rotation axis of the mounting table that passed through the center of the seed crystal substrate was 0°.

Next, the inside of the pressure vessel was evacuated with a vacuum pump. Subsequently, while the heating portion was operated to heat an inside of the pressure vessel so that a temperature in the pressure vessel became 870° C., a nitrogen gas was introduced into the pressure vessel until a pressure therein became 4 MPa, and the pressure vessel (mounting table) was rotated about its central axis at a speed of 20 rpm clockwise and counterclockwise at a certain period, as illustrated in FIG. 4B. The outer vessel was held under the state for 40 hours. Thus, a gallium nitride crystal having a thickness of 700 μm was grown.

After that, the temperature was naturally cooled to room temperature, and the pressure was reduced to atmospheric pressure. After that, the crucible was removed from the inside of the pressure vessel. Solidified metal sodium in the crucible was removed, and a seed crystal substrate in which a gallium nitride crystal had been grown was recovered.

After that, at room temperature, UV laser light was applied from the sapphire substrate side of the seed crystal substrate in which the gallium nitride crystal had been grown to decompose the gallium nitride film of the seed crystal substrate. Thus, the grown gallium nitride crystal was separated from the sapphire substrate.

The separated gallium nitride crystal was fixed to a ceramic-made surface plate for processing, and the gallium polar surface of the gallium nitride was ground and polished with a grinder and a lapping apparatus, and the resultant surface had a mirror finish. Next, the gallium nitride crystal was reversed and fixed to the ceramic-made surface plate for processing, and the nitrogen polar surface thereof was also ground and polished in the same manner as in the gallium polar surface, and the resultant surface had a mirror finish.

Thus, a gallium nitride substrate (wafer) having an off-angle of 0.4° in an a-axis direction, a diameter of 100 mm, and a thickness of 450 μm was produced.

### Experimental Example 1-2

A gallium nitride substrate was produced in the same manner as in Experimental Example 1-1 except that, when the crucible having the seed crystal substrate placed therein was mounted on the mounting table of the growth apparatus, the crucible was mounted at such a position that the above-mentioned angle θ was 90° (in a counterclockwise direction) in the growth of the gallium nitride crystal.

### Experimental Example 1-3

A gallium nitride substrate was produced in the same manner as in Experimental Example 1-1 except that, when the crucible having the seed crystal substrate placed therein was mounted on the mounting table of the growth apparatus, the crucible was mounted at such a position that the above-mentioned angle θ was 180° (in a counterclockwise direction) in the growth of the gallium nitride crystal.

### Experimental Example 1-4

A gallium nitride substrate was produced in the same manner as in Experimental Example 1-1 except that, when the crucible having the seed crystal substrate placed therein was mounted on the mounting table of the growth apparatus, the crucible was mounted at such a position that the above-mentioned angle θ was 270° (in a counterclockwise direction) in the growth of the gallium nitride crystal.

### Experimental Example 2-1

A nitride gallium substrate having an off-angle of 0.4° in an m-axis direction, a diameter of 100 mm, and a thickness of 450 μm was produced in the same manner as in Experimental Example 1-1 except that a sapphire substrate having an off-angle in an a-axis direction and an orientation flat on an a-plane was used as the base substrate in the production of the seed crystal substrate.

### Experimental Example 2-2

A gallium nitride substrate was produced in the same manner as in Experimental Example 2-1 except that, when the crucible having the seed crystal substrate placed therein was mounted on the mounting table of the growth apparatus, the crucible was mounted at such a position that the above-mentioned angle θ was 90° (in a counterclockwise direction) in the growth of the gallium nitride crystal.

### Experimental Example 2-3

A gallium nitride substrate was produced in the same manner as in Experimental Example 2-1 except that, when the crucible having the seed crystal substrate placed therein was mounted on the mounting table of the growth apparatus, the crucible was mounted at such a position that the above-mentioned angle θ was 180° (in a counterclockwise direction) in the growth of the gallium nitride crystal.

### Experimental Example 2-4

A gallium nitride substrate was produced in the same manner as in Experimental Example 2-1 except that, when the crucible having the seed crystal substrate placed therein was mounted on the mounting table of the growth apparatus, the crucible was mounted at such a position that the above-mentioned angle θ was 270° (in a counterclockwise direction) in the growth of the gallium nitride crystal.

### Experimental Example 3-1

A gallium nitride substrate having an off-angle of 0.4° in an a-axis direction, a diameter of 150 mm, and a thickness of 450 μm was produced in the same manner as in Experimental Example 1-1 except that a sapphire substrate having a diameter of 150 mm was used as the base substrate in the production of the seed crystal substrate.

### Experimental Example 3-2

A gallium nitride substrate was produced in the same manner as in Experimental Example 3-1 except that, when the crucible having the seed crystal substrate placed therein was mounted on the mounting table of the growth apparatus, the crucible was mounted at such a position that the above-mentioned angle θ was 90° (in a counterclockwise direction) in the growth of the gallium nitride crystal.

### Experimental Example 3-3

A gallium nitride substrate was produced in the same manner as in Experimental Example 3-1 except that, when the crucible having the seed crystal substrate placed therein was mounted on the mounting table of the growth apparatus, the crucible was mounted at such a position that the above-mentioned angle θ was 180° (in a counterclockwise direction) in the growth of the gallium nitride crystal.

### Experimental Example 3-4

A gallium nitride substrate was produced in the same manner as in Experimental Example 3-1 except that, when the crucible having the seed crystal substrate placed therein was mounted on the mounting table of the growth apparatus, the crucible was mounted at such a position that the above-mentioned angle θ was 270° (in a counterclockwise direction) in the growth of the gallium nitride crystal.

### Experimental Example 4-1

A gallium nitride substrate having an off-angle of 0.4° in an m-axis direction, a diameter of 150 mm, and a thickness of 450 μm was produced in the same manner as in Experimental Example 2-1 except that a sapphire substrate having a diameter of 150 mm was used as the base substrate in the production of the seed crystal substrate.

### Experimental Example 4-2

A gallium nitride substrate was produced in the same manner as in Experimental Example 4-1 except that, when the crucible having the seed crystal substrate placed therein was mounted on the mounting table of the growth apparatus, the crucible was mounted at such a position that the above-mentioned angle θ was 90° (in a counterclockwise direction) in the growth of the gallium nitride crystal.

### Experimental Example 4-3

A gallium nitride substrate was produced in the same manner as in Experimental Example 4-1 except that, when the crucible having the seed crystal substrate placed therein was mounted on the mounting table of the growth apparatus, the crucible was mounted at such a position that the above-mentioned angle θ was 180° (in a counterclockwise direction) in the growth of the gallium nitride crystal.

### Experimental Example 4-4

A gallium nitride substrate was produced in the same manner as in Experimental Example 4-1 except that, when the crucible having the seed crystal substrate placed therein was mounted on the mounting table of the growth apparatus, the crucible was mounted at such a position that the above-mentioned angle θ was 270° (in a counterclockwise direction) in the growth of the gallium nitride crystal.

### <Evaluation>

Each of the resultant gallium nitride substrates was subjected to the following evaluations. The evaluation results are summarized in Tables 1 to 4.

### 1. Carrier Concentration

The carrier concentrations at nine points indicated by black circles 1 to 9 illustrated in FIG. 7 were measured by Hall effect measurement using the van der Pauw method. The black circle 3 is the center of a wafer. The black circles 1, 5, 6, and 9 are the positions at which an a-axis or an m-axis intersects with a circle having an outer periphery at a position apart by 6 mm from an outer edge of the wafer. The black circles 2, 4, 7, and 8 are the positions at which the a-axis or the m-axis intersects with a circle having an outer periphery halfway between the center of the wafer and the outer edge of the wafer (at a position apart by 50 mm from the center in the case of a diameter of 100 mm or at a position apart by 75 mm from the center in the case of a diameter of 150 mm).

From one gallium nitride substrate, nine chip samples each cut out to a size measuring 6 mm×6 mm along the a-axis and the m-axis including the above-mentioned predetermined positions at the center of a square, were obtained. On each of four corners of each of the surfaces of the resultant chip samples, a Ti film having a thickness of 15 nm, an Al film having a thickness of 220 nm, a Ni film having a thickness of 40 nm, and a Au film having a thickness of 75 nm were formed in the stated order with a vacuum vapor deposition apparatus using an electron beam, to form an electrode, followed by annealing at a temperature of 700° C. for 30 seconds under a nitrogen atmosphere, to thereby provide a measurement sample.

The resultant measurement sample was subjected to Hall effect measurement with a Hall measurement system (“ResiTest 8300”, manufactured by TOYO Corporation) to measure the carrier concentration.

The measurement results are summarized in Tables 1A to 4A. In Tables 1 and 3, Distribution 1 shows values calculated from the values of the black circles 1, 2, 3, 4, and 5 by the following formula, and Distribution 2 shows values calculated from the values of the black circles 6, 7, 3, 8, and 9 by the following formula. In Tables 2 and 4, Distribution 1 shows values calculated from the values of the black circles 6, 7, 3, 8, and 9 by the following formula, and Distribution 2 shows values calculated from the values of the black circles 1, 2, 3, 4, and 5 by the following formula.

(maximum value−minimum value)/(average value) Formula:

### 2. Defect Density

The defect densities at the nine points indicated by the black circles 1 to 9 illustrated in FIG. 7 were measured by a cathode luminescence (CL) method.

Specifically, nine chip samples were produced in the same manner as in the measurement of the carrier concentration described in the section 1, and a CL image was obtained for each of the chip samples with a scanning electron microscope (“S-3400N”, manufactured by Hitachi High-Technologies Corporation) under the conditions of an acceleration voltage of 15 kV and an emission current of 100 uA through use of a cathode luminescence detector as a detector, and dark spots were measured in an image capture area of a 80 μm square. The measurement results are summarized in Tables 1B to 4B.

### 3. Warp

The warp (unit: μm) of the gallium nitride substrate was measured with a flatness measuring instrument (“Flatness Tester FT-17”, manufactured by Nidek Co. Ltd.). The flatness measuring instrument is a device that measures the warp by analyzing the shape and crude density of interference fringes obtained by oblique incidence of laser light.

TABLE 1A

| | Θ | Carrier concentration × 10¹⁸ (/cm³) | | | | | | | | | Distribution 1 | Distribution 2 | Warp |
|---|---|---|---|---|---|---|---|---|---|---|---|---|---|
| 100 mm | (°) | 1 | 2 | 3 | 4 | 5 | 6 | 7 | 8 | 9 | (%) | (%) | (μm) |
| Experimental | 0 | 4.13 | 4.07 | 4.02 | 3.88 | 3.65 | 3.95 | 3.91 | 3.95 | 4.01 | 12.2 | 2.8 | 17 |
| Example 1-1 | | | | | | | | | | | | | |
| Experimental | 90 | 3.96 | 3.97 | 3.97 | 4.07 | 3.95 | 3.96 | 4.05 | 3.95 | 3.97 | 3.0 | 2.5 | 55 |
| Example 1-2 | | | | | | | | | | | | | |
| Experimental | 180 | 3.78 | 3.94 | 3.98 | 4.08 | 4.10 | 3.86 | 3.90 | 3.95 | 3.97 | 8.0 | 3.1 | 38 |
| Example 1-3 | | | | | | | | | | | | | |
| Experimental | 270 | 4.01 | 3.95 | 4.03 | 3.97 | 3.97 | 3.95 | 3.98 | 3.95 | 3.94 | 2.0 | 2.0 | 43 |
| Example 1-4 | | | | | | | | | | | | | |

TABLE 2A

| | Θ | Carrier concentration x 10¹⁸ (/cm³) | | | | | | | | | Distribution 1 | Distribution 2 | Warp |
|---|---|---|---|---|---|---|---|---|---|---|---|---|---|
| 100 mm | (°) | 6 | 7 | 3 | 8 | 9 | 1 | 2 | 4 | 5 | (%) | ( %) | (μm) |
| Experimental | 0 | 4.14 | 4.04 | 3.97 | 3.87 | 3.47 | 3.97 | 3.88 | 3.96 | 4.07 | 17.2 | 4.8 | 22 |
| Example 2-1 | | | | | | | | | | | | | |
| Experimental | 90 | 4.07 | 3.97 | 3.98 | 4.05 | 3.86 | 4.00 | 3.99 | 4.03 | 3.98 | 5.3 | 2.0 | 53 |
| Example 2-2 | | | | | | | | | | | | | |
| Experimental | 180 | 3.67 | 3.90 | 3.98 | 4.16 | 4.18 | 3.86 | 3.96 | 3.88 | 4.07 | 12.8 | 3.1 | 42 |
| Example 2-3 | | | | | | | | | | | | | |
| Experimental | 270 | 3.95 | 4.01 | 4.05 | 4.06 | 3.90 | 3.95 | 3.90 | 3.88 | 3.93 | 4.1 | 4.3 | 60 |
| Example 2-4 | | | | | | | | | | | | | |

TABLE 3A

| | Θ | Carrier concentration × 10¹⁸ (/cm³) | | | | | | | | | Distribution 1 | Distribution 2 | Warp |
|---|---|---|---|---|---|---|---|---|---|---|---|---|---|
| 150 mm | (°) | 1 | 2 | 3 | 4 | 5 | 6 | 7 | 8 | 9 | (%) | (%) | (μm) |
| Experimental | 0 | 4.18 | 4.10 | 3.93 | 3.88 | 3.60 | 3.97 | 3.89 | 3.95 | 4.04 | 14.7 | 3.8 | 28 |
| Example 3-1 | | | | | | | | | | | | | |
| Experimental | 90 | 3.90 | 3.69 | 3.86 | 3.77 | 3.75 | 3.89 | 3.95 | 3.97 | 4.03 | 5.5 | 4.3 | 71 |
| Example 3-2 | | | | | | | | | | | | | |
| Experimental | 180 | 3.89 | 3.91 | 4.02 | 4.18 | 4.22 | 3.95 | 3.88 | 3.87 | 4.01 | 8.2 | 3.6 | 49 |
| Example 3-3 | | | | | | | | | | | | | |
| Experimental | 270 | 4.06 | 3.86 | 4.04 | 3.91 | 3.94 | 3.95 | 3.91 | 3.97 | 3.97 | 5.0 | 3.3 | 83 |
| Example 3-4 | | | | | | | | | | | | | |

TABLE 4A

| | Θ | Carrier concentration × 10¹⁸ (/cm³) | | | | | | | | | Distribution 1 | Distribution 2 | Warp |
|---|---|---|---|---|---|---|---|---|---|---|---|---|---|
| 150 mm | (°) | 6 | 7 | 3 | 8 | 9 | 1 | 2 | 4 | 5 | (%) | (%) | (μm) |
| Experimental | 0 | 4.31 | 4.09 | 4.07 | 3.94 | 3.53 | 4.00 | 3.92 | 4.01 | 4.10 | 19.7 | 4.5 | 25 |
| Example 4-1 | | | | | | | | | | | | | |
| Experimental | 90 | 4.26 | 4.16 | 3.99 | 4.11 | 4.03 | 3.92 | 3.99 | 4.01 | 3.95 | 6.5 | 2.3 | 55 |
| Example 4-2 | | | | | | | | | | | | | |
| Experimental | 180 | 3.82 | 4.10 | 4.06 | 4.22 | 4.36 | 4.01 | 3.92 | 3.92 | 3.95 | 13.2 | 3.5 | 41 |
| Example 4-3 | | | | | | | | | | | | | |
| Experimental | 270 | 4.07 | 4.18 | 4.10 | 4.16 | 4.08 | 3.93 | 4.06 | 3.98 | 4.04 | 2.8 | 4.2 | 43 |
| Example 4-4 | | | | | | | | | | | | | |

TABLE 1B

| | Θ | Defect density x 10⁶ (/cm²) | | | | | | | | | Distribution 1 | Distribution 2 | Warp |
|---|---|---|---|---|---|---|---|---|---|---|---|---|---|
| 100 mm | (°) | 1 | 2 | 3 | 4 | 5 | 6 | 7 | 8 | 9 | (%) | (%) | (μm) |
| Experimental | 0 | 2.31 | 2.19 | 1.98 | 1.78 | 1.20 | 2.03 | 2.05 | 2.00 | 2.30 | 58.7 | 15.4 | 17 |
| Example 1-1 | | | | | | | | | | | | | |
| Experimental | 90 | 2.08 | 2.09 | 2.02 | 1.95 | 1.89 | 2.05 | 1.98 | 1.98 | 2.05 | 10.0 | 3.5 | 55 |
| Example 1-2 | | | | | | | | | | | | | |
| Experimental | 180 | 1.53 | 1.80 | 2.05 | 2.13 | 2.09 | 1.98 | 1.95 | 2.03 | 2.16 | 31.3 | 10.3 | 38 |
| Example 1-3 | | | | | | | | | | | | | |
| Experimental | 270 | 1.91 | 2.03 | 2.09 | 2.06 | 2.14 | 1.98 | 2.08 | 2.05 | 2.20 | 11.2 | 10.6 | 43 |
| Example 1-4 | | | | | | | | | | | | | |

TABLE 2B

| | Θ | Defect density × 10⁶ (/cm²) | | | | | | | | | Distribution 1 | Distribution 2 | Warp |
|---|---|---|---|---|---|---|---|---|---|---|---|---|---|
| 100 mm | (°) | 6 | 7 | 3 | 8 | 9 | 1 | 2 | 4 | 5 | (%) | (%) | (μm) |
| Experimental | 0 | 2.70 | 2.22 | 2.02 | 1.78 | 0.83 | 2.13 | 2.06 | 2.11 | 2.33 | 97.9 | 14.6 | 22 |
| Example 2-1 | | | | | | | | | | | | | |
| Experimental | 90 | 1.94 | 1.89 | 2.05 | 2.11 | 1.72 | 2.08 | 2.05 | 2.08 | 2.17 | 20.1 | 5.8 | 53 |
| Example 2-2 | | | | | | | | | | | | | |
| Experimental | 180 | 0.92 | 1.13 | 1.80 | 2.06 | 2.41 | 2.06 | 2.02 | 2.08 | 2.22 | 89.5 | 20.6 | 42 |
| Example 2-3 | | | | | | | | | | | | | |
| Experimental | 270 | 2.28 | 2.22 | 1.98 | 2.27 | 1.88 | 2.08 | 2.14 | 2.09 | 2.30 | 18.8 | 15.1 | 60 |
| Example 2-4 | | | | | | | | | | | | | |

TABLE 3B

| | Θ | Defect density × 10⁶ (/cm²) | | | | | | | | | Distribution 1 | Distribution 2 | Warp |
|---|---|---|---|---|---|---|---|---|---|---|---|---|---|
| 150 mm | (°) | 1 | 2 | 3 | 4 | 5 | 6 | 7 | 8 | 9 | ( %) | (%) | (μm) |
| Experimental | 0 | 2.41 | 2.38 | 2.23 | 1.80 | 1.38 | 2.11 | 2.09 | 2.11 | 2.42 | 50.6 | 15.1 | 28 |
| Example 3-1 | | | | | | | | | | | | | |
| Experimental | 90 | 2.08 | 2.31 | 2.25 | 2.17 | 2.08 | 2.05 | 2.06 | 2.03 | 2.11 | 10.6 | 10.5 | 71 |
| Example 3-2 | | | | | | | | | | | | | |
| Experimental | 180 | 1.63 | 2.05 | 2.05 | 2.31 | 2.11 | 2.13 | 2.02 | 2.06 | 2.22 | 33.5 | 9.5 | 49 |
| Example 3-3 | | | | | | | | | | | | | |
| Experimental | 270 | 2.00 | 2.33 | 2.35 | 2.30 | 2.17 | 2.08 | 2.13 | 2.11 | 2.33 | 15.3 | 11.8 | 83 |
| Example 3-4 | | | | | | | | | | | | | |

TABLE 4B

| | Θ | Defect density × 10⁶ (/cm²) | | | | | | | | | Distribution 1 | Distribution 2 | Warp |
|---|---|---|---|---|---|---|---|---|---|---|---|---|---|
| 150 mm | (°) | 6 | 7 | 3 | 8 | 9 | 1 | 2 | 4 | 5 | (%) | (%) | (μm) |
| Experimental | 0 | 2.80 | 2.56 | 2.05 | 1.94 | 0.96 | 2.17 | 2.08 | 2.11 | 2.44 | 89.3 | 18.0 | 25 |
| Example 4-1 | | | | | | | | | | | | | |
| Experimental | 90 | 2.11 | 1.91 | 2.25 | 2.05 | 1.83 | 2.09 | 2.06 | 2.02 | 2.11 | 20.7 | 10.9 | 55 |
| Example 4-2 | | | | | | | | | | | | | |
| Experimental | 180 | 1.20 | 1.31 | 2.06 | 2.28 | 2.55 | 2.06 | 2.06 | 2.11 | 2.30 | 71.7 | 11.3 | 41 |
| Example 4-3 | | | | | | | | | | | | | |
| Experimental | 270 | 1.95 | 2.11 | 2.30 | 2.51 | 2.42 | 2.05 | 2.19 | 2.16 | 2.33 | 24.8 | 12.7 | 43 |
| Example 4-4 | | | | | | | | | | | | | |

The Group-III element nitride substrate according to at least one embodiment of the present invention may be utilized as, for example, each of the substrates of various semiconductor devices.

According to the embodiment of the present invention, a Group-III element nitride substrate in which the occurrence of warping is suppressed can be provided.

What is claimed is:

1. A Group-III element nitride substrate, comprising a first main surface and a second main surface facing each other,
wherein the Group-III element nitride substrate has a first direction, which extends in a surface direction, and in which a carrier concentration is decreased from a first end portion side to a second end portion side, in a substrate surface of the Group-III element nitride substrate.

2. The Group-III element nitride substrate according to claim 1, wherein the carrier concentration is monotonously decreased from the first end portion side to the second end portion side in the first direction.

3. The Group-III element nitride substrate according to claim 1, wherein the carrier concentration on a line along the first direction has a distribution of 7% or more.

4. The Group-III element nitride substrate according to claim 3,
wherein the Group-III element nitride substrate has a second direction, which extends in the surface direction, and which is perpendicular to the first direction, in the substrate surface, and
wherein the carrier concentration on a line along the second direction has a distribution of less than 7%.

5. The Group-III element nitride substrate according to claim 1, wherein the carrier concentration on a line along the first direction has a distribution of 10% or more.

6. The Group-III element nitride substrate according to claim 5,
wherein the Group-III element nitride substrate has a second direction, which extends in the surface direction, and which is perpendicular to the first direction, in the substrate surface, and
wherein the carrier concentration on a line along the second direction has a distribution of less than 10%.

7. A Group-III element nitride substrate, comprising a first main surface and a second main surface facing each other,
wherein the Group-III element nitride substrate has a first direction, which extends in a surface direction, and in which a defect density is decreased from a first end portion side to a second end portion side, in a substrate surface of the Group-III element nitride substrate.

8. The Group-III element nitride substrate according to claim 7, wherein the defect density is monotonously decreased from the first end portion side to the second end portion side in the first direction.

9. The Group-III element nitride substrate according to claim 7, wherein the defect density on a line along the first direction has a distribution of 30% or more.

10. The Group-III element nitride substrate according to claim 9,
wherein the Group-III element nitride substrate has a second direction, which extends in the surface direction, and which is perpendicular to the first direction, in the substrate surface, and
wherein the defect density on a line along the second direction has a distribution of less than 30%.

11. The Group-III element nitride substrate according to claim 7, wherein the defect density on a line along the first direction has a distribution of 50% or more.

12. The Group-III element nitride substrate according to claim 11,
wherein the Group-III element nitride substrate has a second direction, which extends in the surface direction, and which is perpendicular to the first direction, in the substrate surface, and
wherein the defect density on a line along the second direction has a distribution of less than 50%.

13. The Group-III element nitride substrate according to claim 1, wherein the first direction substantially corresponds to a direction in which a c-axis of a Group-III element nitride crystal is tilted with respect to a normal of the main surface in plan view.

14. The Group-III element nitride substrate according to claim 13, wherein an angle of the tilt is more than 0° and less than 1°.

15. The Group-III element nitride substrate according to claim 1, wherein the Group-III element nitride substrate is a freestanding substrate of a Group-III element nitride crystal.

16. A method of producing the Group-III element nitride substrate of claim 1, the method comprising:
preparing a seed crystal substrate including: a base substrate including an upper surface and a lower surface facing each other; and a seed crystal film to be formed on the upper surface of the base substrate;
growing a Group-III element nitride crystal on the seed crystal film of the seed crystal substrate by a flux method; and
removing the base substrate from the Group-III element nitride crystal,
wherein the growing the Group-III element nitride crystal by the flux method is performed by arranging the seed crystal substrate on a mounting table that is rotated about a vertical axis,
wherein a center of the seed crystal substrate is spaced apart from a rotation axis of the mounting table, and
wherein the seed crystal substrate is arranged so that an angle formed by an off-angle direction of the seed crystal film of the seed crystal substrate and a normal of the rotation axis of the mounting table that passes through the center of the seed crystal substrate is substantially 0° in plan view.

17. The production method according to claim 16, wherein the base substrate contains a material different in composition from the Group-III element nitride crystal.

18. The Group-III element nitride substrate according to claim 7, wherein the first direction substantially corresponds to a direction in which a c-axis of a Group-III element nitride crystal is tilted with respect to a normal of the main surface in plan view.

19. The Group-III element nitride substrate according to claim 7, wherein the Group-III element nitride substrate is a freestanding substrate of a Group-III element nitride crystal.

20. A method of producing the Group-III element nitride substrate of claim 7, the method comprising:
preparing crystal substrate including: a base substrate including an upper surface and a lower surface facing each other; and a seed crystal film to be formed on the upper surface of the base substrate;
growing a Group-III element nitride crystal on the seed crystal film of the seed crystal substrate by a flux method; and
removing the base substrate from the Group-III element nitride crystal,
wherein the growing the Group-III element nitride crystal by the flux method is performed by arranging the seed crystal substrate on a mounting table that is rotated about a vertical axis,
wherein a center of the seed crystal substrate is spaced apart from a rotation axis of the mounting table, and
wherein the seed crystal substrate is arranged so that an angle formed by an off-angle direction of the seed crystal film of the seed crystal substrate and a normal of the rotation axis of the mounting table that passes through the center of the seed crystal substrate is substantially 0° in plan view.
